(19) United States
(12) Patent Application Publication
(10) Pub. No.: US 2026/0262494 A1
(43) Pub. Date: Sep. 3, 2026

(54) Electric Circuit Body and Power Conversion Device

(71) Applicant: Hitachi Astemo, Ltd., Hitachinaka-shi, Ibaraki (JP)

(72) Inventors: Nobutake TSUYUNO, Tokyo (JP); Eiichi IDE, Tokyo (JP); Yujiro KANEKO, Hitachinaka-shi, Ibaraki (JP)

(21) Appl. No.: 18/878,701

(22) PCT Filed: May 16, 2023
(86) PCT No.: PCT/JP2023/018279

§ 371 Date: Dec. 24, 2024

(30) Foreign Application Priority Data
Jul. 4, 2022 (JP) 2022-108049

(51) Int. Cl. H10W 40/20; H02M 7/00; H10W 74/10

(52) U.S. Cl. CPC H10W 40/242; H02M 7/003; H10W 74/111

(57) ABSTRACT

An electric circuit body includes a semiconductor device incorporating a semiconductor element and having a heat dissipating portion of the semiconductor element, the heat dissipating portion being formed on at least one surface, a cooling member disposed facing the heat dissipating portion of the semiconductor device and configured to cool heat generated by the semiconductor element, a heat conduction member disposed between the semiconductor device and the cooling member, and a resin member disposed between the semiconductor device and the cooling member and on an outer side of a projection region of the heat dissipating portion in a stacking direction of the semiconductor device and the cooling member to be in close contact with the heat conduction member, wherein the resin member has smaller compression set than the heat conduction member.

### TECHNICAL FIELD

The present invention relates to an electric circuit body and a power conversion device.

### BACKGROUND ART

A power conversion device using a switching operation of a semiconductor element has high conversion efficiency, and thus is widely used for consumer use, in-vehicle use, railway use, transformation equipment, and the like. The semiconductor element generates heat by energization. Therefore, a cooling member for cooling a semiconductor element is provided, and a heat conduction member is disposed between the semiconductor device incorporating the semiconductor element and the cooling member disposed to face the semiconductor device. The heat conduction member conducts heat generation from the semiconductor element to the cooling member by bringing the semiconductor device and the cooling member into close contact with each other. Cooling of a semiconductor device is required to have high reliability maintaining heat dissipation property particularly in in-vehicle applications.

PTL 1 discloses a technique for filling an insulating resin in a gap between a power card and an accommodating portion and curing the insulating resin to fix the power card in an inverter equipped with a housing formed with the accommodating portion configured to accommodate the power card in which both surfaces of a semiconductor element is sandwiched with heat sinks and a circulation path for circulating a cooling medium at the periphery of the power card.

### CITATION LIST

### Patent Literature

PTL 1: JP 2005-237141 A

### SUMMARY OF INVENTION

### Technical Problem

In PTL 1, measures of outflow of the heat conduction member, and the like are not considered, and the reliability of the device is decreased.

### Solution to Problem

An electric circuit body according to the present invention includes a semiconductor device incorporating a semiconductor element and having a heat dissipating portion of the semiconductor element, the heat dissipating portion being formed on at least one surface, a cooling member disposed facing the heat dissipating portion of the semiconductor device and configured to cool heat generated by the semiconductor element, a heat conduction member disposed between the semiconductor device and the cooling member, and a resin member disposed between the semiconductor device and the cooling member and on an outer side of a projection region of the heat dissipating portion in a stacking direction of the semiconductor device and the cooling member to be in close contact with the heat conduction member, wherein the resin member has smaller compression set than the heat conduction member.

### Advantageous Effects of Invention

According to the present invention, a highly reliable device that suppresses outflow of a heat conduction member can be provided.

### BRIEF DESCRIPTION OF DRAWINGS

FIG. 1 is a plan view of an electric circuit body according to an embodiment.

FIG. 2 is a cross-sectional view taken along line X-X of the electric circuit body.

FIG. 3 is a cross-sectional perspective view taken along line Y-Y of the electric circuit body.

FIG. 4 is a cross-sectional perspective view taken along line X-X of the electric circuit body.

FIG. 5 is a semi-transparent plan view of the semiconductor device.

FIG. 6 is a circuit diagram of the semiconductor device.

FIGS. 7(a), 7(b), 7(c), and 7(d) are cross-sectional views for explaining manufacturing steps of the semiconductor device.

FIGS. 8(a) and 8(b) are cross-sectional views for explaining manufacturing steps of the electric circuit body.

FIGS. 9(a), 9(b), and 9(c) are cross-sectional views for explaining plastic deformation of the heat conduction member according to a comparative example.

FIGS. 10(a), 10(b), and 10(c) are cross-sectional views for explaining plastic deformation of the heat conduction member according to the embodiment.

FIGS. 11(a), 11(b), 11(c), and 11(d) are plan views illustrating the arrangement of a resin member.

FIGS. 12(a) and 12(b) are cross-sectional views illustrating an embodiment and a comparative example of an electric circuit body.

FIG. 13 is a circuit diagram of a power conversion device using a semiconductor device.

FIG. 14 is an outer appearance perspective view of the power conversion device.

FIG. 15 is a cross-sectional perspective view of the power conversion device.

### DESCRIPTION OF EMBODIMENTS

Hereinafter, embodiments of the present invention will be described with reference to the drawings. The following description and drawings are examples for describing the present invention, and are omitted and simplified as appropriate for the sake of clarity of description. The present invention can be implemented in various other forms. Unless otherwise specified, each component may be singular or plural.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the position, size, shape, range, and the like disclosed in the drawings.

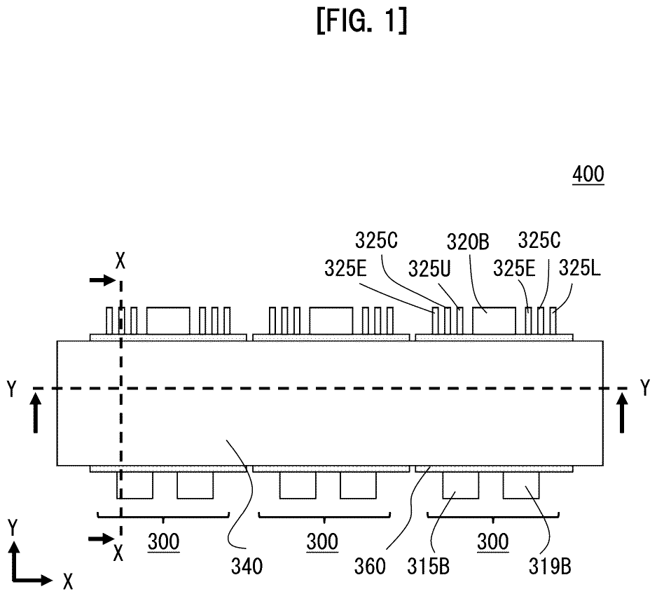

FIG. 1 is a plan view of an electric circuit body 400 according to an embodiment.

The electric circuit body 400 includes a semiconductor device 300 and a cooling member 340. In the example illustrated in FIG. 1, the electric circuit body 400 includes three semiconductor devices 300 provided in parallel.

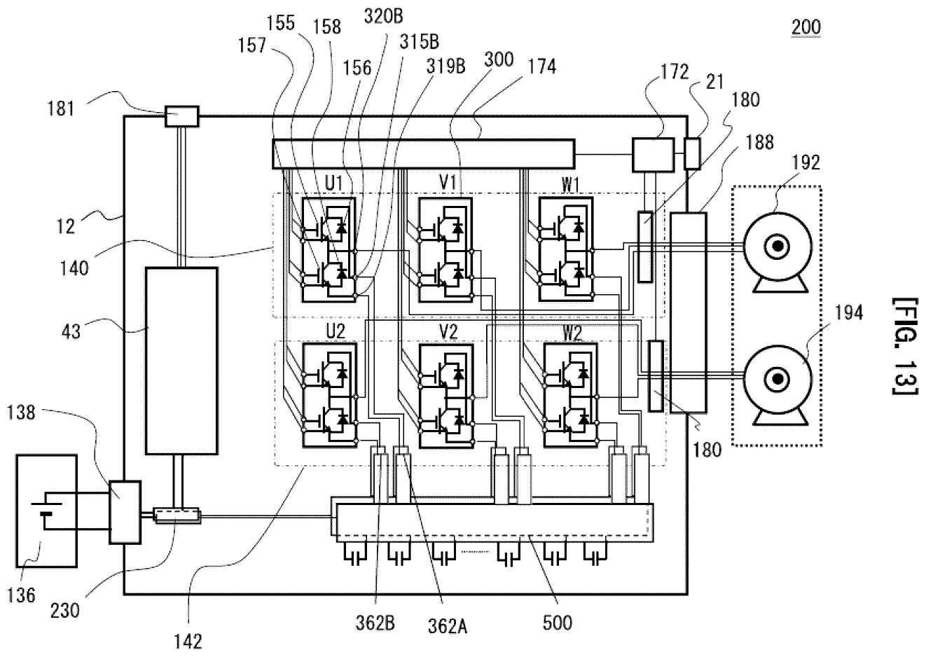

In the semiconductor device 300, semiconductor elements 155 and 157 to be described later are incorporated by being sealed with a sealing material 360. Both surfaces of the semiconductor elements 155 and 157 are formed with heat dissipating portions that dissipate heat by the switching operations of the semiconductor elements 155 and 157. Furthermore, in the semiconductor device 300, terminals connected to the semiconductor elements 155 and 157 are led out from the sealing material 360 on the side surface of the semiconductor device 300. These terminals are power terminals through which a large current flows, such as a positive electrode side terminal 315B and a negative electrode side terminal 319B coupled to a capacitor module 500 (see FIG. 13) of a DC circuit, and an AC side terminal 320B coupled to motor generators 192 and 194 (see FIG. 13) of an AC circuit. In addition, the terminals led out from the sealing material 360 on the side surface of the semiconductor device 300 are terminals such as a lower arm gate terminal 325L, a collector sense terminal 325C, an emitter sense terminal 325E, and an upper arm gate terminal 325U. The electric circuit body 400 provided with three semiconductor devices 300 in parallel functions as a power conversion device that converts a DC current and an AC current by switching operations of the semiconductor elements 155 and 157. Note that the number of semiconductor devices 300 included in the electric circuit body 400 is not limited to three, and is arbitrarily set according to various forms of the electric circuit body 400.

The cooling member 340 is disposed to face the heat dissipating portion of the semiconductor device 300, and cools heat generation by the switching operation of the semiconductor elements 155 and 156. Specifically, the cooling member 340 is formed with a flow path through which the refrigerant flows, and cools the heat generation of the semiconductor device 300 by the refrigerant flowing through the flow path. As the refrigerant, water, an anti-freezing fluid in which ethylene glycol is mixed with water, or the like is used. The cooling member 340 is desirably made of aluminum-based material having high thermal conductivity and light weight. The cooling member 340 is manufactured by extrusion molding, forging, brazing, or the like.

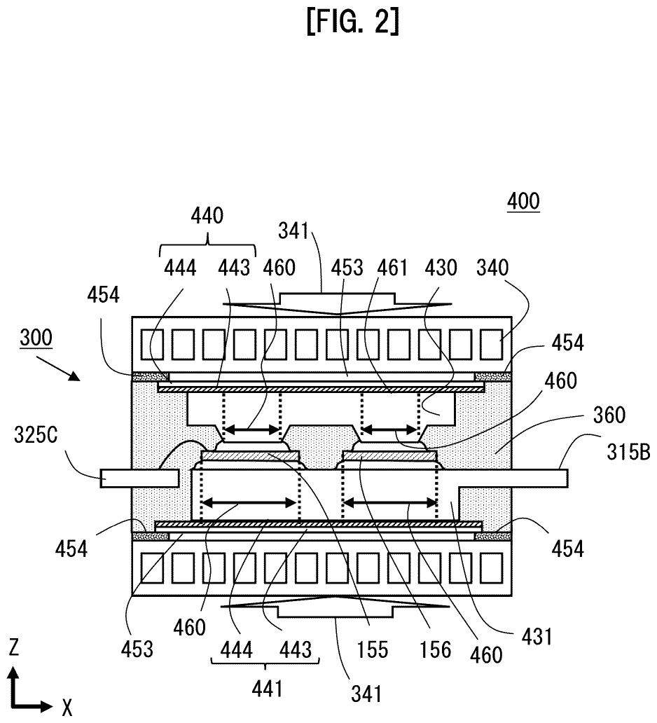

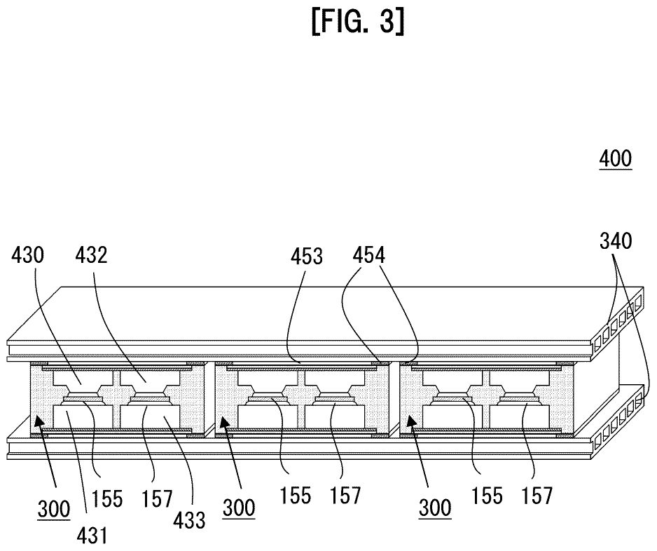

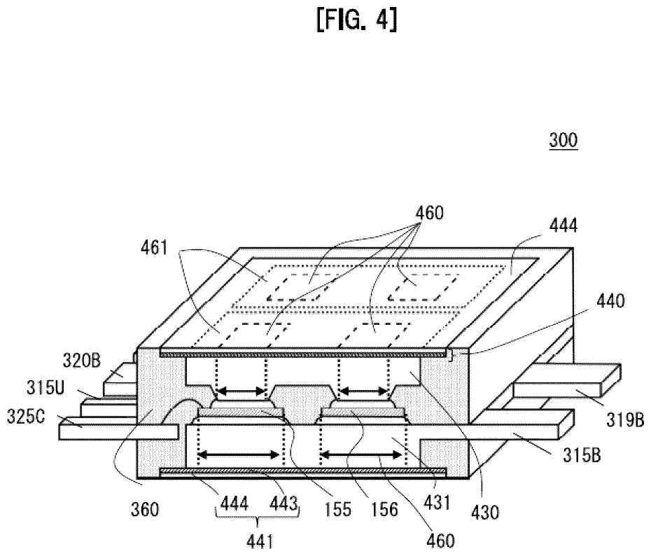

FIG. 2 is a cross-sectional view taken along line X-X of the electric circuit body 400 illustrated in FIG. 1, and FIG. 3 is a cross-sectional perspective view taken along line Y-Y of the electric circuit body 400 illustrated in FIG. 1. FIG. 4 is a cross-sectional perspective view taken along line X-X of the electric circuit body 400 illustrated in FIG. 1, and illustrates the semiconductor device 300 in which cooling member 340 and the heat conduction member 453 are removed from the electric circuit body 400.

As illustrated in FIG. 2, the electric circuit body 400 includes a pressurizing mechanism 341 configured to sandwich and pressurize the cooling members 340 provided on both surfaces of the semiconductor device 300 from both surfaces. Although illustrated in a simplified manner, the pressurizing mechanism 341 is, for example, a mechanism that couples the cooling members 340 on both surfaces to each other with bis or the like to pressurize the cooling members 340 toward the semiconductor device 300 side.

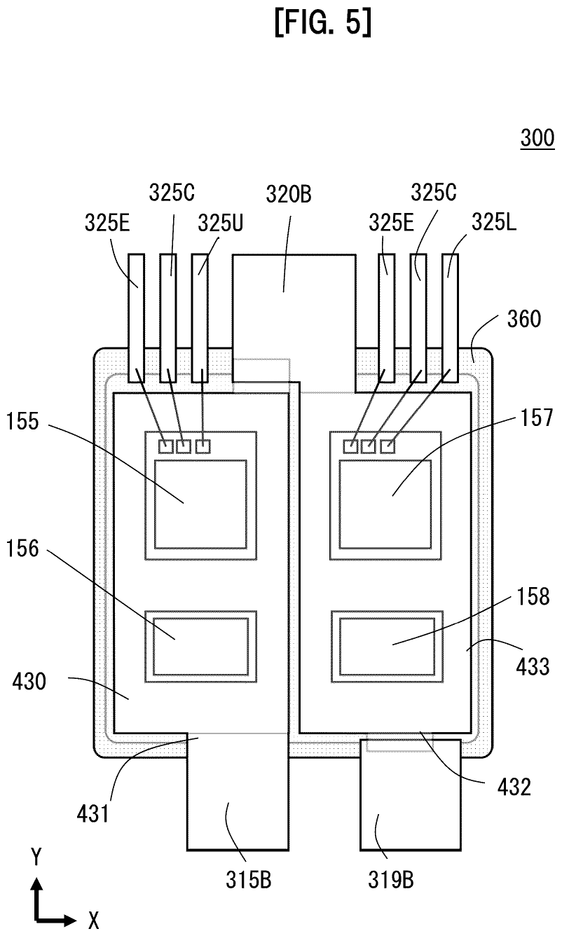

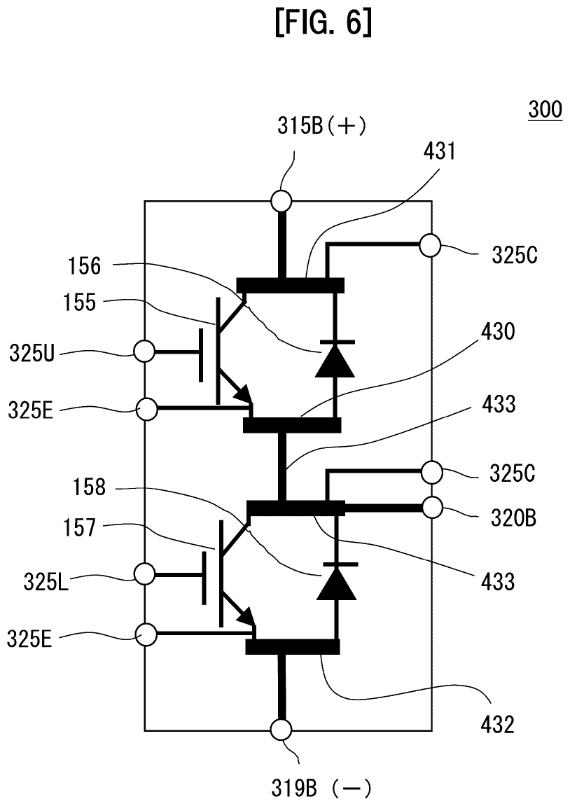

As illustrated in FIG. 2, an active element 155 and a diode 156 are provided as first semiconductor elements forming an upper arm circuit of the power conversion device (see FIGS. 5 and 6 to be described later). As the active element, Si, Sic, GaN, GaO, C, or the like can be used. When the body diode of the active element 155 is used, the separately attached diode may be omitted. A collector side of the first semiconductor element 155 is joined to a second conductor plate 431. For this joining, solder may be used or sintered metal may be used. A first conductor plate 430 is joined to an emitter side of the first semiconductor element 155.

As illustrated in FIG. 3, an active element 157 and a diode 158 are provided as second semiconductor elements forming a lower arm circuit (see FIGS. 5 and 6 to be described later). As illustrated in FIG. 3, a collector side of the second semiconductor element 157 is joined to a fourth conductor plate 433. A third conductor plate 432 is joined to an emitter side of the second semiconductor element 157.

The conductor plates 430, 432, and 433 are not particularly limited as long as they are materials having high electrical conductivity and thermal conductivity, but it is desirable to use a metal-based material such as a copper-based or aluminum-based material, a composite material of a metal-based material and high thermal conductivity diamond, carbon, ceramic, or the like. These may be used alone, but may be subjected to plating with Ni, Ag, or the like in order to improve the joining property with solder or sintered metal.

As illustrated in FIGS. 2, 3 and 4, the conductor plates 430, 431, 432, and 433 serve as a heat transfer member that transfers heat generated by the semiconductor elements 155, 156, 157, and 158 to the cooling member 340, in addition to a role of energizing current. Since the conductor plates 430, 431, 432, and 433 and the cooling member 340 have different potentials, it is desirable to use insulation sheets 440 and 441 therebetween.

The resin insulating layer 443 of the insulation sheets 440 and 441 is not particularly limited as long as they have adhesiveness with a heat sink, but an epoxy resin-based resin insulating layer in which a powdery inorganic filler is dispersed is desirable. This is because the balance between adhesiveness and heat dissipation property is good. The insulation sheets 440 and 441 may be a resin insulating layer 443 alone, but it is desirable to provide a metal foil 444 on the side to come into contact with the heat conduction member 453 to be described later. The insulation sheets 440 and 441 are cured simultaneously with the sealing material 360 in the transfer molding step. In the transfer mold forming step, when the insulation sheets 440 and 441 are mounted on a die, a release sheet or a metal foil 444 is provided on a contact surface between the insulation sheets 440 and 441 and the die to prevent adhesion to the die. Since the release sheet has poor thermal conductivity, a step of peeling off the release sheet after transfer molding is required, but in a case where the metal foil 444 is used, it can be used without being peeled off after transfer molding by selecting a copper-based or aluminum-based metal having high thermal conductivity.

The semiconductor elements 155, 156, 157, and 158, the conductor plates 430, 431, 432, and 433, and the insulation sheets 440 and 441 are sealed with a sealing material 360 by transfer mold forming to configure a semiconductor device 300.

As illustrated in FIG. 2, in order to reduce contact thermal resistance between the semiconductor device 300 and the cooling member 340, a heat conduction member 453 is disposed between the semiconductor device 300 and the cooling member 340. Furthermore, the resin member 454 is disposed between the semiconductor device 300 and the cooling member 340 and on the outer side of the projection region 460 of the heat dissipating portion in the stacking direction of the semiconductor device 300 and the cooling member 340 in close contact with the heat conduction member 453.

In order to secure workability and long-term reliability, the heat conduction member 453 is a curable resin cured product having fluidity in an uncured state and having no fluidity after being cured. The curable resin cured product has low viscosity and excellent workability at the time of application, and has an advantage that mechanical properties can be improved by being cured. Thermal curing, moisture curing, ultraviolet curing, and the like can be used for curing, but thermal curing is desirable for curing to a deep portion. Since the heat conduction member 453 brings the semiconductor device 300 and the cooling member 340 having different coefficients of thermal expansion into close contact, the stress needs to be set low. Therefore, the Young's modulus of the heat conduction member 453 is desirably less than or equal to 50 MPa. The Young's modulus in the present embodiment is a value measured at a frequency of 10 Hz, a strain of 0.1%, and a temperature of 25° C. in a dynamic viscoelasticity test in a tensile or compressing direction.

The heat conduction member 453 is a material in which a filler is mixed with a resin. The resin is most desirably a silicone resin having a small change in elastic modulus from around −40° C. to around 200° C. The filler is a high heat conductive material such as a metal, a ceramic, or a carbon-based material.. Since the resin is filled with the filler to reduce the elastic modulus, the heat conduction member 453 becomes a cured product having a large compression set and being easily subjected to plastic deformation. The compression set in the present embodiment is a strain remaining after 30 minutes from when a compression displacement of 10% is applied at room temperature for 30 minutes and unloaded.

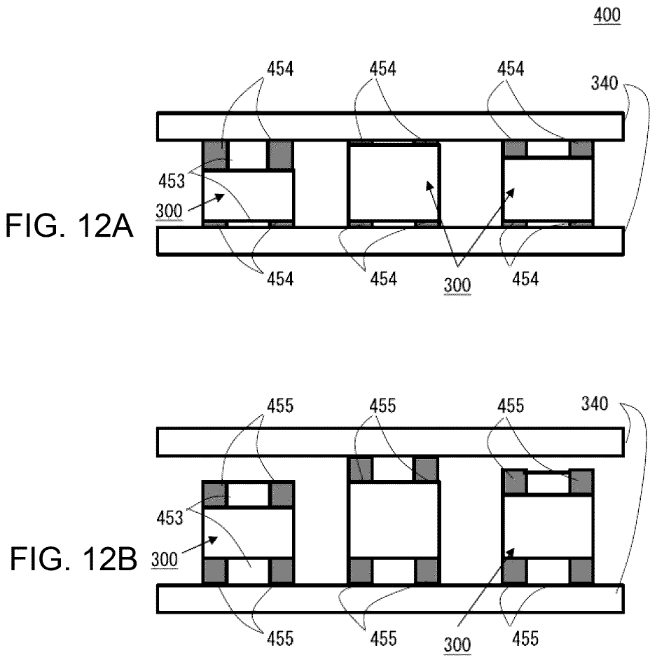

The resin member 454 is a curable resin cured product having fluidity in an uncured state and no fluidity after being cured for workability and heat dissipation property. The curable resin cured product has low viscosity and excellent workability at the time of application, and can function as a spacer between the semiconductor device 300 and the cooling member 340 by being thinned to the same thickness as the heat conduction member 453 by pressurization and cured. Therefore, as compared with a case where a spacer having a constant thickness is disposed, the heat conduction member 453 can be thinned, and the heat dissipation property is improved. This point will be described later with reference to FIG. 12.

The Young's modulus of the resin member 454 is desirably higher than the Young's modulus of the heat conduction member 453. The resin member 454 is disposed on the outer side of the projection region 460 so as to be in close contact with the heat conduction member 453, and between the semiconductor device 300 and the cooling member 340, the stress is made higher than the stress of the heat conduction member 453 to suppress plastic deformation of the heat conduction member 453.

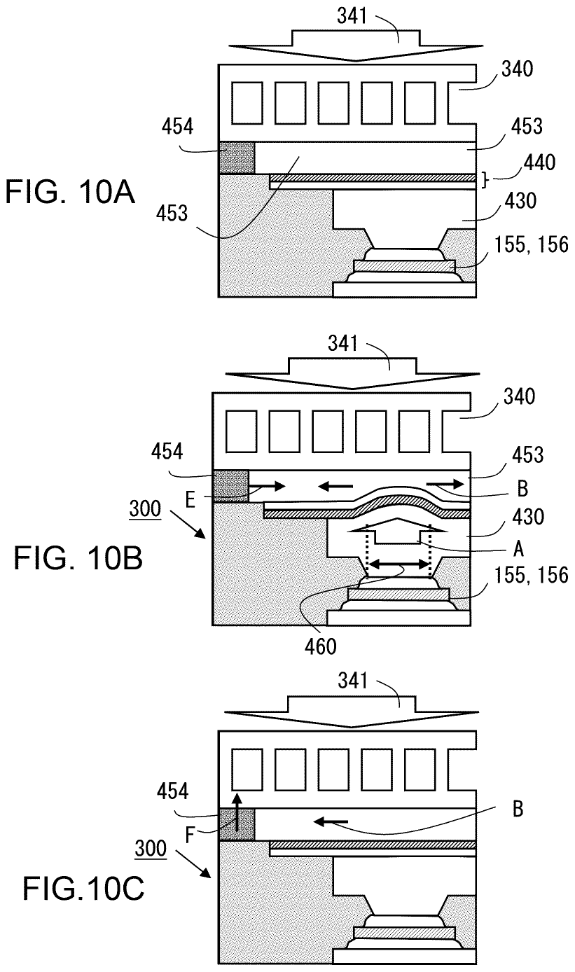

As the resin member 454, a resin such as a silicone resin may be used alone, or a material obtained by mixing a filler with this resin may be used. In any case, the cured product has a smaller compression set than the heat conduction member 453. Since the resin member 454 has a smaller compression set than the heat conduction member 453, the pressurizing force for pressing the cooling member 340 against the semiconductor device 300 by the pressurizing mechanism 341 is shared, and the heat conduction member 453 can be suppressed from being plastically deformed and flowing out to the outside of the semiconductor device 300. That is, the load sharing of the resin member 454 is set to be larger than the load sharing of the heat conduction member 453. This point will be described later with reference to FIG. 10.

The resin member 454 is disposed at least on the outer side of the projection region 460 of the heat dissipating portion in the stacking direction of the semiconductor device 300 and the cooling member 340 as illustrated in FIG. 4. As a result, the heat of the semiconductor elements 155 to 158 can be conducted to the heat conduction member 453 without being hindered by the resin member 454. Alternatively, resin member 454 may be disposed on the outer side of the projection region 461 of the conductor plates 430, 431, 432, and 433 in the stacking direction of semiconductor device 300 and cooling member 340. As a result, heat conducted from the semiconductor elements 155 and 156 through the conductor plates 430, 431, 432, and 433 can be conducted to the heat conduction member 453 without being hindered by the resin member 454. Note that in any case, the resin member 454 is made of a material obtained by mixing a filler, which is a high heat conductive material, with a resin, so that heat conduction is less than that of the heat conduction member 453, but it is possible to prevent the heat conduction from being greatly hindered. Furthermore, in any case, a filler or the like is blended such that the Young's modulus of the resin member 454 is higher than the Young's modulus of the heat conduction member 453.

FIG. 5 is a semi-transparent plan view of the semiconductor device 300. FIG. 6 is a circuit diagram of the semiconductor device 300.

As illustrated in FIGS. 5 and 6, the positive electrode side terminal 315B is output from the collector side of the upper arm circuit, and is connected to the positive electrode side of the battery or the capacitor. The upper arm gate terminal 325U is output from the gate of the active element 155 of the upper arm circuit. A negative electrode side terminal 319B is output from an emitter side of a lower arm circuit, and is connected to a negative electrode side of the battery or the capacitor or the GND. The lower arm gate terminal 325L is output from the gate of the active element 157 of the lower arm circuit. An AC side terminal 320B is output from the collector side of the lower arm circuit and is connected to a motor. When a neutral point is grounded, the lower arm circuit is connected not to the GND but to the negative electrode side of the capacitor.

The emitter sense terminal 325E of the upper arm is output from the emitter of the active element 155 of the upper arm circuit, and the emitter sense terminal 325E of the lower arm is output from the emitter of the active element 157 of the lower arm circuit. The collector sense terminal 325C of the upper arm is output from the collector of the active element 155 of the upper arm circuit, and the collector sense terminal 325C of the lower arm is output from the collector of the active element 157 of the lower arm circuit.

In addition, a conductor plate (upper arm circuit emitter side) 430 and a conductor plate (upper arm circuit collector side) 431 are disposed above and below the active element 155 and the diode 156 of the power semiconductor element (upper arm circuit). A conductor plate (lower arm circuit emitter side) 432 and a conductor plate (lower arm circuit collector side) 433 are arranged above and below the active element 157 and the diode 158 of the power semiconductor element (lower arm circuit).

The semiconductor device 300 of the present embodiment has a 2 in 1 structure, which is a structure in which two arm circuits of the upper arm circuit and the lower arm circuit are integrated into one module. In addition, a structure in which a plurality of upper arm circuits and lower arm circuits are integrated into one module may be used. In this case, the number of output terminals from the semiconductor device 300 can be reduced and the size can be reduced.

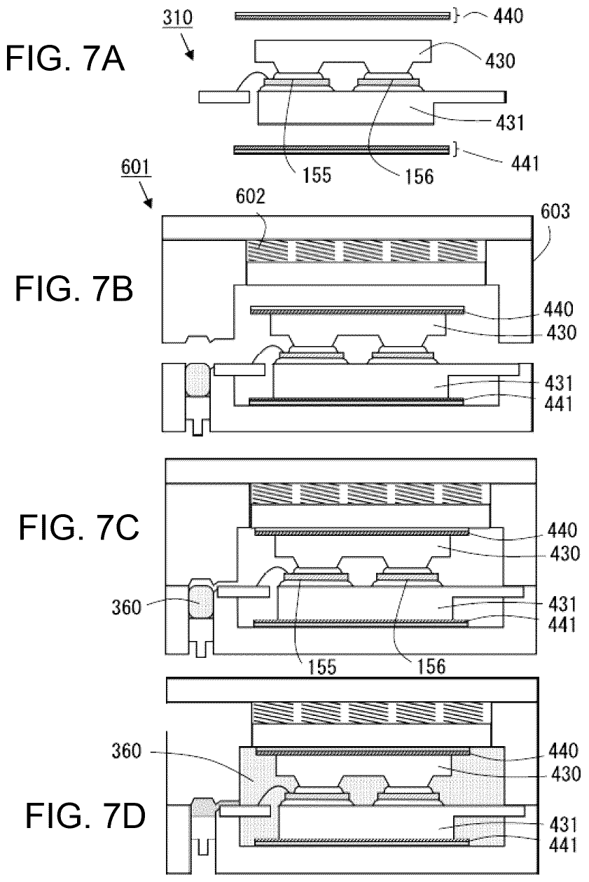

FIGS. 7(a), 7(b), 7(c), and 7(d) are cross-sectional views for explaining the manufacturing steps of the semiconductor device 300. Similarly to FIG. 2, a cross-sectional view taken along line X-X of one module is illustrated.

FIG. 7(a) is a temporary attaching step. The collector side of the semiconductor element 155 and the cathode side of the semiconductor element 156 are connected to the second conductor plate 431, and the gate electrode, the emitter sense electrode, and the collector electrode of the semiconductor element 155 are connected to the gate terminal 325U, the emitter sense terminal 325E, and the collector sense terminal 325C of the upper arm, respectively, by wire bonding. Furthermore, the emitter side of the semiconductor element 155 and the anode side of the semiconductor element 156 are connected to the first conductor plate 430 to produce the circuit body 310 on the upper arm side. Similarly, the collector side of the semiconductor element 157 and the cathode side of the semiconductor element 158 are connected to the fourth conductor plate 433, and the gate electrode, the emitter sense electrode, and the collector electrode of the semiconductor element 157 are connected to the gate terminal 325L, the emitter sense terminal 325E, and the collector sense terminal 325C of the lower arm, respectively, by wire bonding.

Furthermore, the emitter side of the semiconductor element 157 and the anode side of the semiconductor element 158 are connected to the third conductor plate 432 to produce the circuit body 310 on the lower arm side. However, in FIG. 7(a), only the circuit body 310 on the upper arm side is illustrated, and the circuit body 310 on the lower arm side is not illustrated. Thereafter, the insulation sheets 440 and 441 are temporarily attached to the conductor plates 430 to 433. The temporary attachment is to temporarily attach using the adhesive force of the insulation sheets 440 and 441 under a condition that there is room for curing and adhering the insulation sheets 440 and 441 in the subsequent transfer molding step.

FIGS. 7(b) through 7(d) illustrate a transfer molding step. The transfer molding device 601 includes a spring 602 in a die 603. With the spring 602, even if the height of the circuit body 310 varies, a predetermined load can be applied by the force of the spring 602 without applying excessive pressure to the semiconductor elements 155 to 158. Furthermore, the transfer molding device 601 includes a vacuum degassing mechanism (not illustrated). Through vacuum degassing, even when the sealing material 360 or the like made of resin or the like involves voids, the voids can be compressed to be small, and the insulation properties can be improved. In addition, it is possible to protect the resin burr from entering the spring drive unit and the like by covering the circuit body 310 with a release film (not illustrated).

As illustrated in FIG. 7(b), the circuit body 310 on which the insulation sheets 440 and 441 are temporarily attached is set in the die 603 heated to a constant temperature state of 175° C. in advance. Next, as illustrated in FIG. 7(c), the upper and lower dies 603 are clamped. At this time, the insulation sheets 440 and 441 and the conductor plates 430 to 433 are pressurized and brought into close contact with each other by the spring 602. The conductor plates 431 and 433 located on the collector side are pressurized toward the lower die 603 when the terminal portions on the outer peripheries of the conductor plates 431 and 433 are clamped by the die, and are added to the force of the spring 602, so that the conductor plates 431 and 433 are crimped to the insulation sheet 441 with a stronger force than the conductor plates 430 and 432 located on the emitter side.

Thereafter, as illustrated in FIG. 7(d), the sealing material 360 is injected into the die 603. Thereafter, the resin-sealed semiconductor device 300 is taken out from the transfer molding device 601, and post-curing is performed at 175° C. for 2 or more hours.

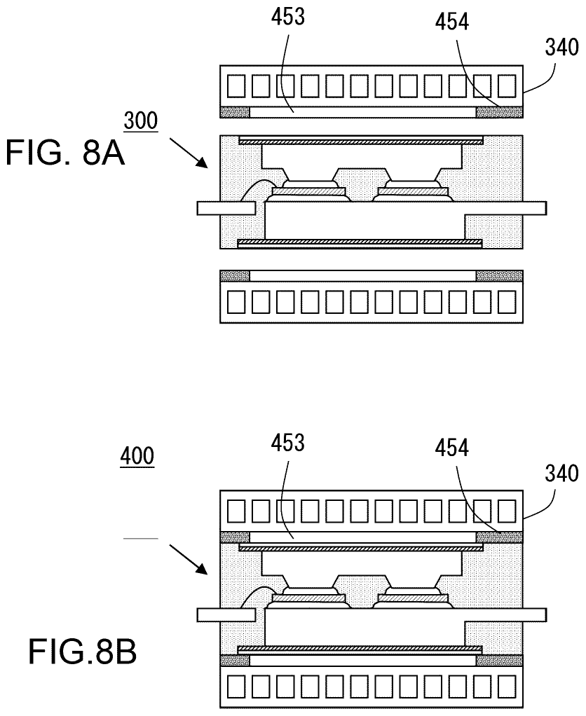

FIGS. 8(a) and 8(b) are cross-sectional views for explaining manufacturing steps of the electric circuit body 400. This step is performed using the semiconductor device 300 manufactured by the step illustrated in FIG. 7(d).

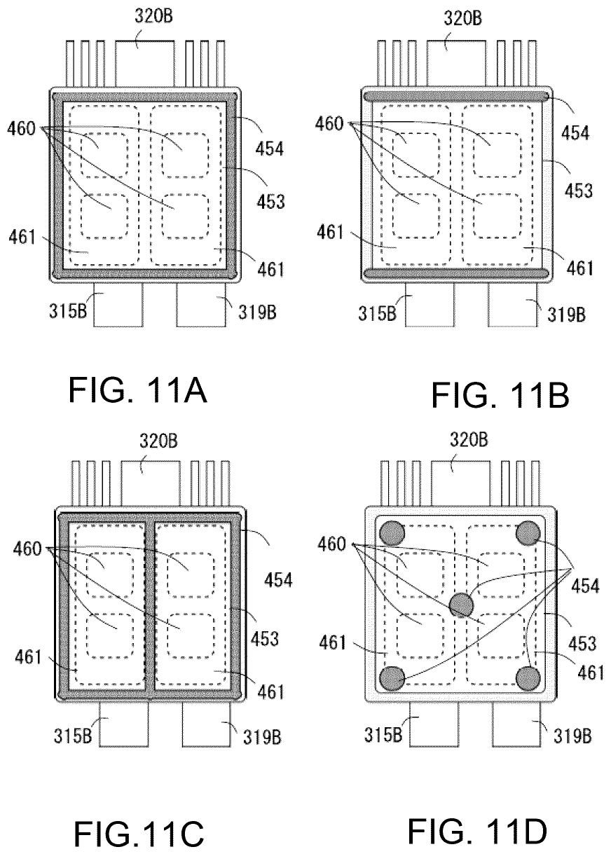

FIG. 8(a) illustrates an applying step. The heat conduction member 453 and the resin member 454 are applied to the cooling member 340. The portion to be applied and the like will be described later with reference to FIG. 11.

FIG. 8(b) illustrates a close contact/curing step. The cooling member 340 to which heat conduction member 453 and the resin member 454 are applied is brought into close contact with the semiconductor device 300. Then, the heat conduction member 453 and the resin member 454 are cured to produce the electric circuit body 400.

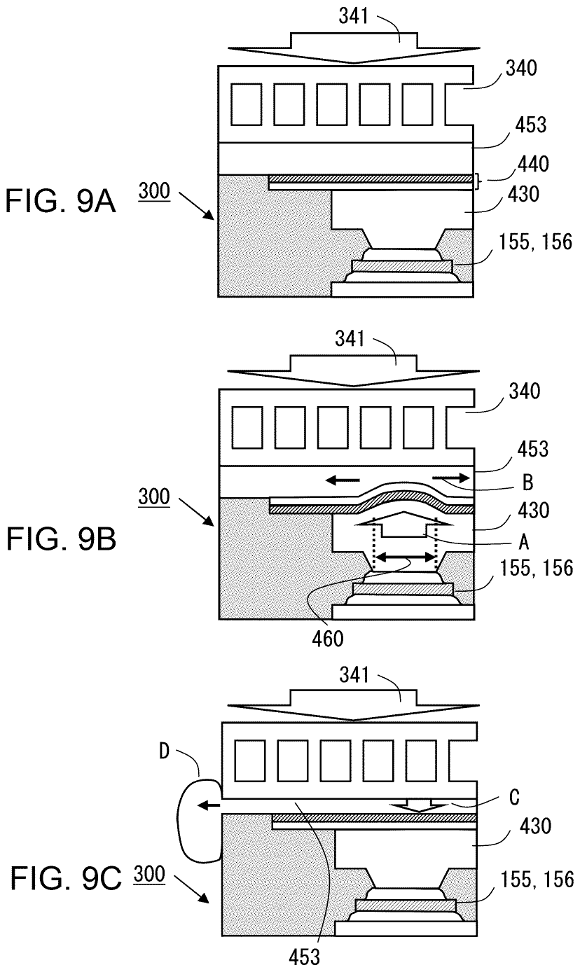

FIGS. 9(a), 9(b), and 9(c) are cross-sectional views for explaining plastic deformation of the heat conduction member 453 according to a comparative example. This comparative example is a case where the present embodiment is not applied.

As illustrated in FIG. 9(a), the heat conduction member 453 is pressurized by the pressurizing mechanism 341 and is brought into close contact with the semiconductor device 300.

As illustrated in FIG. 9(b), when the semiconductor elements 155 and 156 generate heat by energization, the temperature of the conductor plate 430 joined to the semiconductor elements 155 and 156 rises, and the conductor plate 430 thermally expands locally in the direction of the arrow A toward the cooling member 340 around the projection region 460 of the heat dissipating portion. As a result, the heat conduction member 453 is locally compressed and plastically deformed, and is pushed out to the outer side B of the projection region 460.

As illustrated in FIG. 9(c), when the energization to the semiconductor elements 155 and 156 is stopped and the conductor plate 430 is cooled, the local thermal expansion of the conductor plate 430 returns to the original state. The site where the heat conduction member 453 is plastically deformed cannot share the pressurizing force C of the pressurizing mechanism 341 as the compressive stress reduces by the plastic deformation. Therefore, the pressurizing force C of the pressurizing mechanism 341 increases the pressurizing force with respect to the heat conduction member 453 on the outer side of the projection region 460 that is not plastically deformed. As a result, the heat conduction member 453 on the outer side of the projection region 460 plastically deforms, the heat conduction member 453 flows out to the outside D of the semiconductor device 300, and the thickness of the heat conduction member 453 reduces. In addition, by repeating this outflow, the density of the filler filled in the heat conduction member 453 becomes sparse, and the heat dissipation property of the heat conduction member 453 reduces. In addition, when the heat conduction member 453 that has flowed out comes into contact with a terminal or the like led out from the semiconductor device 300, there is a concern that insulation property may deteriorate.

FIGS. 10(a), 10(b), and 10(c) are cross-sectional views for explaining plastic deformation of the heat conduction member 453 according to the present embodiment.

As illustrated in FIG. 10(a), the heat conduction member 453 and the resin member 454 are pressurized by the pressurizing mechanism 341 and are in close contact with the semiconductor device 300.

As illustrated in FIG. 10(b), when the semiconductor elements 155 and 156 generate heat by energization, the temperature of the conductor plate 430 joined to the semiconductor elements 155 and 156 rises, and the conductor plate 430 thermally expands locally in the direction of the arrow A toward the cooling member 340 around the projection region 460 of the heat dissipating portion. As a result, the heat conduction member 453 is locally compressed and plastically deformed, and attempts to move to the outer side B of the projection region 460. However, since the resin member 454 having smaller compression set than that of the heat conduction member 453 is disposed between the semiconductor device 300 and the cooling member 340 and on the outer side of the projection region 460 of the heat dissipating portion, the force with which the heat conduction member 453 attempts to move to the outer side B is pushed back in the direction of the arrow E by the repulsive force of the resin member 454, and this movement is suppressed.

As illustrated in FIG. 10(c), when the energization to the semiconductor elements 155 and 156 is stopped and the conductor plate 430 is cooled, the local thermal expansion of the conductor plate 430 returns to the original state. Since the site where the heat conduction member 453 is plastically deformed does not share the pressurizing force of the pressurizing mechanism 341 due to plastic deformation, the pressurizing force applied to the heat conduction member 453 on the outer side B of the projection region 460 increases. However, since the resin member 454 has a smaller compression set than the heat conduction member 453, the resin member 454 shares this pressurizing force as indicated by an arrow F. In other words, since the load sharing of the resin member 454 is set to be larger than the load sharing of the heat conduction member 453, the resin members 454 share the pressurizing force. As a result, reduction in the thickness of the heat conduction member 453 can be suppressed. Since the thickness of the heat conduction member 453 does not change, large-scale movement and outflow of the heat conduction member 453 can be prevented. As a result, a decrease in heat dissipation property is suppressed. In addition, it is possible to suppress and prevent the heat conduction member 453 from flowing out to the outside of the semiconductor device 300 and reaching the terminal or the like by disposing the resin member 454 on the terminal side of the semiconductor device 300.

FIGS. 11(a), 11(b), 11(c), and 11(d) are plan views illustrating the arrangement of the resin member 454. In all cases, in the semi-transparent plan view of the semiconductor device 300 illustrated in FIG. 5, the arrangement position of the resin member 454 is illustrated, where FIG. 11(a) illustrates the embodiment, FIG. 11(b) illustrates a first modified example, FIG. 11(c) illustrates a second modified example, and FIG. 11(d) illustrates a third modified example. In these drawings, the heat conduction member 453 is illustrated in a transmission state.

As illustrated in FIG. 11(a), in the present embodiment, the resin member 454 is disposed in a band shape so as to surround the outer periphery of the heat conduction member 453 and to be in close contact with the heat conduction member 453. The resin member 454 is disposed on the outer side of the projection region 461 of the conductor plates 430, 431, 432, and 433. Note that the resin member 454 may be disposed at least on the outer side of the projection region 460 of the heat dissipating portion. The load sharing by the resin member 454 has an effect of suppressing outflow of the heat conduction member 453. In addition, there is an effect of preventing outflow by surrounding the heat conduction member 453 with the resin member 454. Usually, the resin member 454 has a lower thermal conductivity than the heat conduction member 453, but by being disposed on the outer side of the projection region 460 of the heat dissipating portion, deterioration of the cooling performance of the semiconductor device 300 can be suppressed. Furthermore, by disposing the resin member 454 on the outer side of the projection region 460 of the heat dissipating portion, the cooling performance of the semiconductor device 300 can be maintained equivalently to the case where the resin member 454 is not provided.

As illustrated in FIG. 11(b), in the first modified example, the terminals 315B, 319B, and 320B connected to the semiconductor elements 155, 156, 157, and 158 are led out from the side surface of the semiconductor device 300, but the resin member 454 is disposed in a band shape in close contact with the heat conduction member 453 on the side of this side surface. The load sharing by the resin member 454 has an effect of suppressing outflow of the heat conduction member 453. In particular, the outflow of the heat conduction member 453 to the terminal side can be suppressed by disposing the resin member 454 on the terminal side. In addition, in a case where the terminals 315B, 319B, and 320B are on both sides of the side surface of the semiconductor device 300, the resin member 454 can be formed so as to draw double lines, and thus, excellent workability is obtained.

As illustrated in FIG. 11(c), in the second modified example, the resin member 454 is disposed in a band shape between the projection regions 460 of the heat dissipating portions of the plurality of semiconductor elements 155, 156, 157, and 158 incorporated in the semiconductor device 300. Note that the resin member 454 may be disposed between the projection regions 461 of the conductor plates 430, 431, 432, and 433. There is an effect of increasing load sharing by the resin member 454 and suppressing outflow of the heat conduction member 453 while maintaining cooling performance of the semiconductor device 300.

As illustrated in FIG. 11(d), in a third modified example, the resin member 454 is disposed in a dot shape in close contact with the heat conduction member 453 on the outer side of the projection region 460 of the heat dissipating portion. As an example, the resin member 454 is disposed on the outer side of the projection region 460 of the heat dissipating portion and at each of the four corners and the center of the heat conduction member 453. In this case as well, there is an effect of suppressing outflow of the heat conduction member 453 by load sharing of the resin member 454. In addition, since the resin member 454 can be formed in a dot shape, excellent workability is obtained. The shape and the number of the resin members 454 arranged in a dot shape are appropriately set so that the load sharing of the resin member 454 is larger than the load sharing of the heat conduction member 453. Note that in FIGS. 11(a), 11(b), and 11(c), an example in which the resin member 454 is disposed in a band shape has been described, but the resin members 454 may be disposed in a dot shape.

In any of the cases illustrated in FIGS. 11(a), 11(b), 11(c), and 11(d), the resin member 454 sets the volume ratio of the resin member 454 and the heat conduction member 453, the Young's modulus of each of them, the density of the filler, the cross-linked structure of the resin, and the like such that the load sharing becomes larger than the load sharing of the heat conduction member 453.

In FIGS. 11(a), 11(b), 11(c), and 11(d), the description has been made focusing on the heat dissipating portion of the semiconductor elements 155 and 157 on one surface of the semiconductor device 300, but the resin member 454 and the heat conduction member 453 are similarly disposed on the other surfaces of the semiconductor elements 155 and 157. In this case, the arrangement shape of the resin member 454 on the other surface may be the same as the arrangement shape of the resin member 454 on one surface illustrated in FIGS. 11(a), 11(b), 11(c), and 11(d), that is, may be the same on both surfaces, or may be different on both surfaces.

FIGS. 12(a) and 12(b) are cross-sectional views taken along line Y-Y of the electric circuit body 400 illustrated in FIG. 1. FIG. 12(a) illustrates an embodiment of the present invention, and FIG. 12(b) illustrates a comparative example.

As illustrated in FIGS. 12(a) and 12(b), a case where the thickness of the semiconductor device 300 varies in the stacking direction of the semiconductor device 300 and the cooling member 340 is illustrated. In these figures, for the sake of clarity, the variation in thickness is drawn to be large and does not represent the actual thickness.

In the present embodiment, the heat conduction member 453 and the resin member 454 are resin cured products that have fluidity in an uncured state and lose fluidity after curing. Therefore, in the close contact step described with reference to FIG. 8(b), the cooling member 340 to which the heat conduction member 453 and the resin member 454 in the uncured state are applied is brought into close contact with the semiconductor device 300. As illustrated in FIG. 12(a), even if there is a variation in the thickness of the semiconductor device 300, this variation can be absorbed and the cooling member 340 can be brought into close contact with the semiconductor device 300. Thereafter, the heat conduction member 453 and the resin member 454 are cured.

In the comparative example to which the present embodiment is not applied, a case where the solid spacer 455 is used will be described. In this case, the variation in the thickness of the semiconductor device 300 cannot be absorbed, and the cooling member 340 and the semiconductor device 300 are not brought into close contact with each other, so that the reliability of the electric circuit body 400 such as heat dissipation property is deteriorated.

In the present embodiment, since the resin member 454 having a small compression set is disposed in close contact with the heat conduction member 453, it is possible to suppress deterioration of heat dissipation property due to outflow of the heat conduction member 453 and to provide the electric circuit body 400 having high reliability. In addition, since the heat conduction member 453 and the resin member 454 are resin cured products which have fluidity in an uncured state and lose fluidity after curing, it is possible to absorb variations in the thickness of the semiconductor device 300 and the like and to provide the electric circuit body 400 with high reliability without deteriorating heat dissipation property. Furthermore, by disposing the resin member 454 on the terminal side, it is possible to suppress the outflow of the heat conduction member 453 to the terminal side and to provide the electric circuit body 400 with high reliability.

FIG. 13 is a circuit diagram of the power conversion device 200 using the semiconductor device 300.

The power conversion device 200 includes inverter circuit units 140 and 142, an inverter circuit unit 43 for an auxiliary equipment, and a capacitor module 500. The inverter circuit units 140 and 142 include a plurality of semiconductor devices 300, which are connected to configure a three-phase bridge circuit. In a case where the current capacity is large, the semiconductor devices 300 are further connected in parallel, and the parallel connection is performed in correspondence with each phase of the three-phase inverter circuit, thereby responding to an increase in the current capacity. In addition, it is also possible to respond to an increase in current capacity by connecting the active elements 155 and 157 and the diodes 156 and 158, which are semiconductor elements incorporated in the semiconductor device 300, in parallel.

The inverter circuit unit 140 and the inverter circuit unit 142 have the same basic circuit configuration, and basically the same control method and operation. Since an outline of a circuit operation of the inverter circuit unit 140 and the like is well known, a detailed description thereof will be omitted here.

As described above, the upper arm circuit includes the active element 155 for the upper arm and the diode 156 for the upper arm as semiconductor elements for switching, and the lower arm circuit includes the active element 157 for the lower arm and the diode 158 for the lower arm as semiconductor elements for switching. The active elements 155 and 157 perform switching operation in response to a drive signal output from one or the other of the two driver circuits constituting the driver circuit 174, and convert DC power supplied from the battery 136 into three-phase AC power.

As described above, the active element 155 for the upper arm and the active element 157 for the lower arm include a collector electrode, an emitter electrode, and a gate electrode. The diode 156 for the upper arm and the diode 158 for the lower arm include two electrodes, a cathode electrode and an anode electrode. As illustrated in FIG. 6, the cathode electrodes of the diodes 156 and 158 are electrically connected to the collector electrodes of the active elements 155 and 157, respectively, and the anode electrodes are electrically connected to the emitter electrodes of the active elements 155 and 157, respectively. As a result, the current flows in the forward direction from the emitter electrode to the collector electrode of the active element 155 for the upper arm and the active element 157 for the lower arm. The active elements 155 and 157 are, for example, IGBTs.

Note that a metal oxide semiconductor field effect transistor (MOSFET) may be used as the active element, in which case, the diode 156 for the upper arm and the diode 158 for the lower arm are unnecessary.

The positive electrode side terminal 315B and the negative electrode side terminal 319B of each of the upper and lower arm series circuits are respectively connected to a DC terminal for capacitor connection of the capacitor module 500. The AC power is generated at the connecting portion of the upper arm circuit and the lower arm circuit, and the connecting portion of the upper arm circuit and the lower arm circuit of each of the upper and lower arm series circuits is connected to the AC side terminal 320B of each semiconductor device 300. The AC side terminal 320B of each semiconductor device 300 of each phase is connected to the AC output terminal of the power conversion device 200, and the generated AC power is supplied to a stator winding of the motor generator 192 or 194.

The control circuit 172 generates a timing signal for controlling the switching timing of the active element 155 for the upper arm and the active element 157 for the lower arm based on input information from a control device, a sensor (e.g., the current sensor 180), or the like on the vehicle side. The driver circuit 174 generates a drive signal for causing the active element 155 for the upper arm and the active element 157 for the lower arm to perform the switching operation based on the timing signal output from the control circuit 172. Note that reference numerals 181, 182, and 188 denote connectors.

The upper and lower arm series circuits include a temperature sensor (not illustrated), and temperature information of the upper and lower arm series circuits is input to the microcomputer. Voltage information on the DC positive electrode side of the upper and lower arm series circuits is input to the microcomputer. The microcomputer performs overtemperature detection and overvoltage detection based on these pieces of information, stops the switching operation of all the active elements 155 for the upper arm and the active elements 157 for the lower arm when overtemperature or overvoltage is detected to protect the upper and lower arm series circuits from overtemperature or overvoltage.

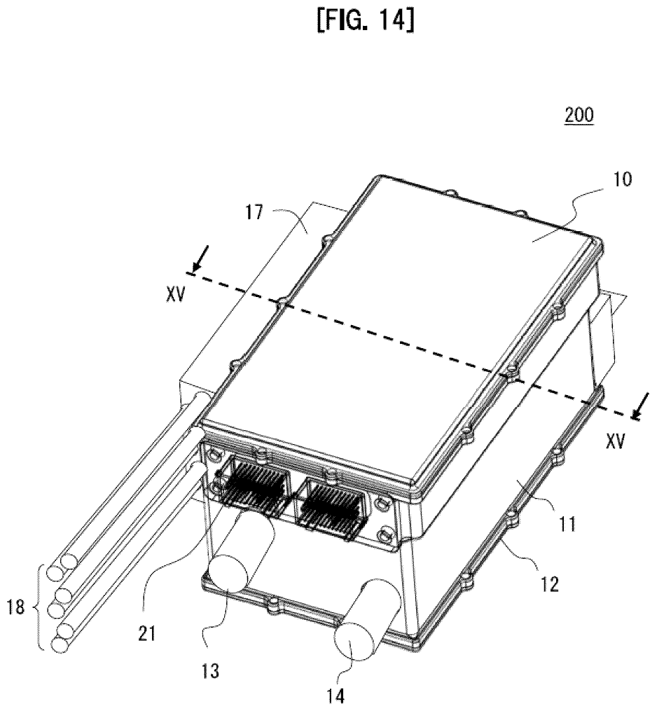

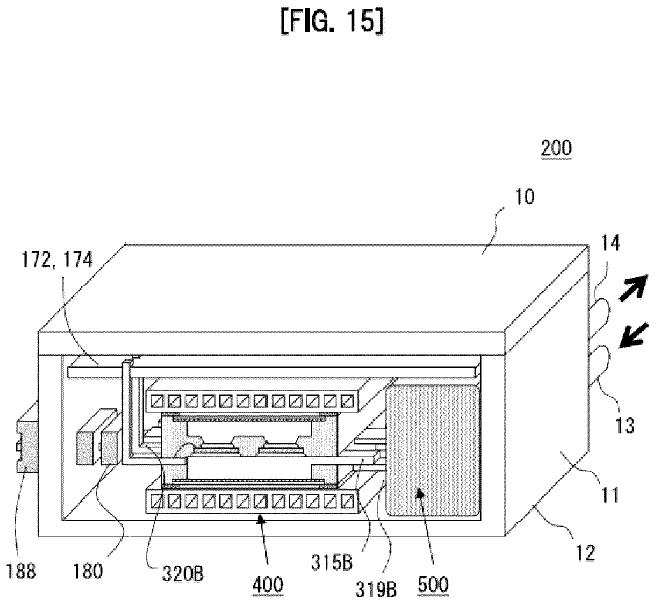

FIG. 14 is an outer appearance perspective view of the power conversion device 200 illustrated in FIG. 13, and FIG. 15 is a cross-sectional perspective view taken along line XV-XV of the power conversion device 200 illustrated in FIG. 14.

The power conversion device 200 includes a housing 12 that is configured by a lower case 11 and an upper case 10 and is formed in a substantially rectangular parallelepiped shape. An electric circuit body 400, a capacitor module 500, and the like are accommodated in the housing 12. The electric circuit body 400 has a cooling flow path flowing to the cooling member 340, and a cooling water inflow pipe 13 and a cooling water outflow pipe 14 communicating with the cooling flow path are protruded from one side surface of the housing 12. An upper side of the lower case 11 is opened, and the upper case 10 is attached to the lower case 11 while closing the opening of the lower case 11. The upper case 10 and the lower case 11 are formed of an aluminum alloy or the like, and are fixed while being sealed with respect to the outside. The upper case 10 and the lower case 11 may be integrated. Since the housing 12 has a simple rectangular parallelepiped shape, attachment to a vehicle or the like is facilitated, and production is facilitated.

A connector 17 is attached to one side surface of the housing 12 in the longitudinal direction, and an AC terminal 18 is connected to the connector 17. Furthermore, a connector 21 is provided on a surface from which the cooling water inflow pipe 13 and the cooling water outflow pipe 14 are led out.

As illustrated in FIG. 15, the electric circuit body 400 is accommodated in the housing 12. The control circuit 172 and the driver circuit 174 are disposed above the electric circuit body 400, and the capacitor module 500 is accommodated on the DC terminal side of the electric circuit body 400. The power conversion device 200 can be thinned, and the degree of freedom in installation on the vehicle is improved by disposing the capacitor module at the same height as the electric circuit body 400. The AC side terminal 320B of the electric circuit body 400 penetrates the current sensor 180 and is connected to the connector 188. Furthermore, the positive electrode side terminal 315B and the negative electrode side terminal 319B, which are DC terminals of the semiconductor device 300, are joined to the positive and negative electrode side terminals 362A and 362B of the capacitor module 500, respectively.

The embodiment described above has the following operation effect.

(1) An electric circuit body 400 includes a semiconductor device 300 incorporating semiconductor elements 155 and 157 and having heat dissipating portions of the semiconductor elements 155 and 157, the heat dissipating portion being formed on at least one surface, a cooling member 340 disposed facing the heat dissipating portion of the semiconductor device 300 and configured to cool heat generated by the semiconductor elements 155 and 157, a heat conduction member 453 disposed between the semiconductor device 300 and the cooling member 340, and a resin member 454 disposed between the semiconductor device 300 and the cooling member 340 and on the outer side of a projection region 460 of the heat dissipating portion in a stacking direction of the semiconductor device 300 and the cooling member 340 so as to be in close contact with the heat conduction member 453, where the resin member 454 has a smaller compression set than that of the heat conduction member 453. Accordingly, a highly reliable device can be provided.

The present invention is not limited to the embodiments described above, and other modes conceivable within the scope of the technical idea of the present invention are also included n the scope of the present invention as long as the characteristics of the present invention are not impaired. In addition, the embodiment described above and a plurality of modified examples may be combined.

### REFERENCE SIGNS LIST

10 upper case
11 lower case
13 cooling water inflow pipe
14 cooling water outflow pipe
17, 21, 181, 182, 188 connector
18 AC terminal
43, 140, 142 inverter circuit unit
155 first semiconductor element (upper arm circuit active element)
156 first semiconductor element (upper arm circuit diode)
157 second semiconductor element (lower arm circuit active element)
158 second semiconductor element (lower arm circuit diode)
172 control circuit
174 driver circuit
180 current sensor
192, 194 motor generator
200 power conversion device
300 semiconductor device
315B positive electrode side terminal
319B negative electrode side terminal
320B AC side terminal
325E emitter sense terminal
325L lower arm gate terminal
325C collector sense terminal
325U upper arm gate terminal
340 cooling member
341 pressurizing mechanism
360 sealing material
400 electric circuit body
420 conductor plate
430 first conductor plate (upper arm circuit emitter side)
431 second conductor plate (upper arm circuit collector side)
432 third conductor plate (lower arm circuit emitter side)
433 fourth conductor plate (lower arm circuit collector side)
440 first insulation sheet (emitter side)
441 second insulation sheet (collector side)
442 first resin insulating layer (emitter side)
443 second resin insulating layer (collector side)
444 metal foil
453 heat conduction member
454 resin member
455 spacer
460 projection region of heat dissipating portion
461 projection region of conductor plate
500 capacitor module
601 transfer molding device
602 spring

1. An electric circuit body comprising:
a semiconductor device incorporating a semiconductor element and having a heat dissipating portion of the semiconductor element, the heat dissipating portion being formed on at least one surface;
a cooling member disposed facing the heat dissipating portion of the semiconductor device and configured to cool heat generated by the semiconductor element;
a heat conduction member disposed between the semiconductor device and the cooling member; and
a resin member disposed between the semiconductor device and the cooling member and on an outer side of a projection region of the heat dissipating portion in a stacking direction of the semiconductor device and the cooling member to be in close contact with the heat conduction member,
wherein the resin member has smaller compression set than the heat conduction member.

2. The electric circuit body according to claim 1, wherein the heat conduction member and the resin member are resin cured products that have fluidity in an uncured state and lose the fluidity after curing.

3. The electric circuit body according to claim 1, wherein a Young's modulus of the resin member is higher than a Young's modulus of the heat conduction member.

4. The electric circuit body according to claim 1, wherein
the semiconductor device includes a conductor plate joined to the semiconductor element, and
the resin member is disposed on an outer side of a projection region of the conductor plate in the stacking direction to be in close contact with the heat conduction member.

5. The electric circuit body according to claim 1, wherein
a terminal connected to the semiconductor element is led out from at least one side surface of the semiconductor device, and
the resin member is disposed on a side of the one side surface from which the terminal is led out.

6. The electric circuit body according to claim 5, wherein the resin member is disposed on an outer periphery of the heat conduction member.

7. The electric circuit body according to claim 6, wherein
the semiconductor device incorporates a plurality of the semiconductor elements, and
the resin member is disposed between projection regions of the heat dissipating portions of the incorporated semiconductor elements.

8. The electric circuit body according to claim 1, wherein the resin member is disposed in a band shape.

9. The electric circuit body according to claim 1, wherein the resin member is disposed in a dot shape.

10. The electric circuit body according to claim 4, wherein the semiconductor device includes an insulation sheet between the conductor plate and the heat conduction member and between the conductor plate and the resin member.

11. The electric circuit body according to claim 1, wherein
the heat dissipating portion is formed on both surfaces of the semiconductor element,
the cooling member is disposed on both surfaces of the semiconductor device facing the heat dissipating portion, and
the heat conduction member and the resin member are disposed on both surfaces between the semiconductor device and the cooling member.

12. A power conversion device comprising the electric circuit body according to claim 1, wherein DC power is converted into AC power.
